(19) United States
(12) Patent Application Publication
(10) Pub. No.: US 2010/0021763 A1
(43) Pub. Date: Jan. 28, 2010

(54) EASY TO WRITE AND HARD TO DECAY MEDIA FOR HARD DISK DRIVE APPLICATIONS

(75) Inventors: Alan Huang, San Jose, CA (US); Connie Chunling Liu, San Jose, CA (US); John Wang, Fremont, CA (US); Romulo Canilon Ata, San Jose, CA (US); Shanghsien Alex Rou, Fremont, CA (US)

Correspondence Address: Shumaker & Sieffert, P.A., 1625 Radio Drive, Suite 300, Woodbury, MN, 55125, US

(73) Assignee: SEAGATE TECHNOLOGY LLC, Scotts Valley, CA (US)

(21) Appl. No.: 12/179,562

(22) Filed: Jul. 24, 2008

(51) Int. Cl. C23C 14/34; G11B 5/33

(52) U.S. Cl. 428/800; 204/192.15

(57) ABSTRACT

A magnetic recording medium is presented, characterized by having a nonmonotonicity in the DCD curve, resulting in low dynamic coercivity when writing information to the medium, with high static coercivity and thermal stability during storage. A method is also presented for producing the magnetic recording medium of the present invention.

### RELATED APPLICATIONS

None.

### BACKGROUND

Conventional magnetic recording media employ high magnetic anisotropy energy density (Ku) materials, often results in higher coercive force (Hc), to achieve better thermal decay in storage media for hard disk drive applications. One of the major adverse effects is the degradation of media writability and often leads to poor bit error rate (BER) performance. As coercivity increases, over write (OW) decreases. This problem is even more pronounced for media having an added mechanical texture utilized to achieve the high orientation.

### SUMMARY

The present invention demonstrates a unique approach to fabricate anti-ferromagnetic coupled (AFC) longitudinal media with a static coercivity above 5000 Oe, and a 2 dB improvement of OW over conventional media design. This invention provides magnetic recording media having different coercivity properties when writing information to the media, compared to the coercivity properties when the media is in storage. This magnetic media has the characteristic of being easy to write and hard to decay (“EWHD”). This media family can be characterized with a “kink” (i.e., a non-monotonicity) in the DC de-magnetized (DCD) curves.

As will be realized, this invention is capable of other and different embodiments, and its details are capable of modifications in various obvious respects, all without departing from this invention. Accordingly, the drawings and description are to be regarded as illustrative in nature and not as restrictive.

### BRIEF DESCRIPTION OF THE DRAWINGS

FIG. 1 is a view of a magnetic disk drive of the related art.

FIG. 2 is a schematic representation of the film structure in accordance with a magnetic recording medium of the present invention.

FIG. 3 is perspective view of a magnetic head and a magnetic disk of the related art.

FIG. 4 is graph of coercive force versus overwrite for conventional media.

FIG. 5 shows the normalized DC de-magnetized curves, exhibiting a kink.

### DETAILED DESCRIPTION

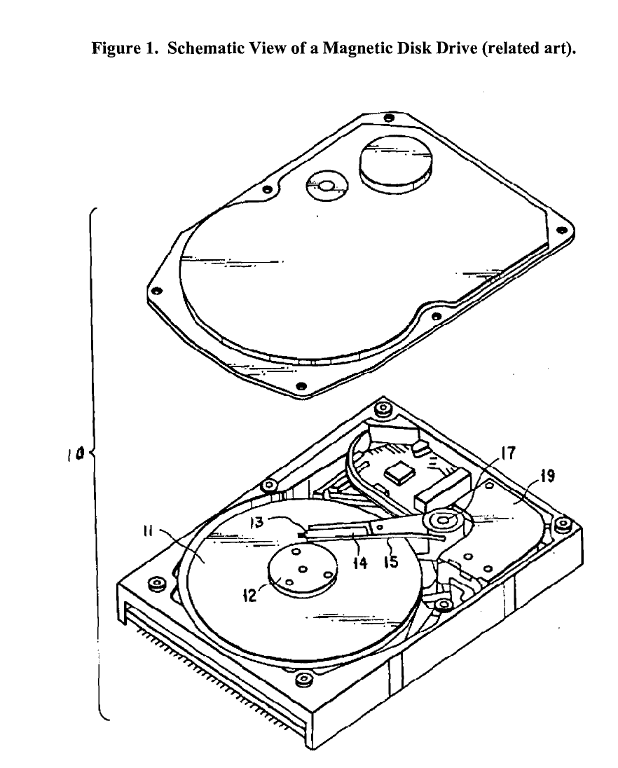

FIG. 1 shows the schematic arrangement of a magnetic disk drive 10 using a rotary actuator. A disk or medium 11 is mounted on a spindle 12 and rotated at a predetermined speed. The rotary actuator includes an arm 15 to which is coupled a suspension 14. A magnetic head 13 is mounted at the distal end of the suspension 14. The magnetic head 13 is brought into contact with the recording/reproduction surface of the disk 11. The rotary actuator could have several suspensions and multiple magnetic heads to allow for simultaneous recording and reproduction on and from both surfaces of each medium.

An electromagnetic converting portion (not shown) for recording/reproducing information is mounted on the magnetic head 13. The arm 15 has a bobbin portion for holding a driving coil (not shown). A voice coil motor 19 as a kind of linear motor is provided to the other end of the arm 15. The voice motor 19 has the driving coil wound on the bobbin portion of the arm 15 and a magnetic circuit (not shown). The magnetic circuit includes a permanent magnet and a counter yoke. The magnetic circuit opposes the driving coil to sandwich it. The arm 15 is swingably supported by ball bearings (not shown) provided at the upper and lower portions of a pivot portion 17. The ball bearings provided around the pivot portion 17 are held by a carriage portion (not shown).

A magnetic head support mechanism is controlled by a positioning servo driving system. The positioning servo driving system includes a feedback control circuit having a head position detection sensor (not shown), a power supply (not shown), and a controller (not shown). When a signal is supplied from the controller to the respective power supplies based on the detection result of the position of the magnetic head 13, the driving coil of the voice coil motor 19 and the piezoelectric element (not shown) of the head portion are driven.

Almost all the manufacturing of a disk media takes place in clean rooms where the amount of dust in the atmosphere is kept very low, and is strictly controlled and monitored. After one or more cleaning processes on a non-magnetic substrate, the substrate has an ultra-clean surface and is ready for the deposition of layers of magnetic media on the substrate. The apparatus for depositing all the layers needed for such media could be a static sputter system or a pass-by system, where all the layers except the lubricant are deposited sequentially inside a suitable vacuum environment.

Magnetic media structures are typically made to include a series of thin films deposited on top of aluminum substrates, ceramic substrates or glass substrates. A conventional magnetic media structure including a seed layer, under-layer, one or more magnetic layers and a protective layer. The glass substrate is typically a high quality glass having few defects

The seed layer is typically a thin film made of chromium based amorphous alloy such as CrTiₓ (X<60), CoW_{y} (Y<90) or B2 structure alloy such as NiAl_{z} (Z=50), that forms the foundation for structures that are deposited on top of it. Under-layer, deposited on top of the seed layer, normally consists of a couple of Cr based BCC structural non-magnetic layers, such as Cr, and/or CrMoxTayMnz (X≦30, Y≦10, Z≦10). Magnetic layers, deposited on top of the under-layer, typically include a stack of several magnetic and non-magnetic layers. The magnetic layers are typically made out of magnetic alloys containing cobalt (Co), platinum (Pt) and chromium (Cr), whereas the non-magnetic layers are typically made out of metallic non-magnetic materials. Finally, a protective overcoat is a thin film typically made of carbon with hydrogen or nitrogen, which is deposited on top of the magnetic layers using conventional thin film deposition techniques

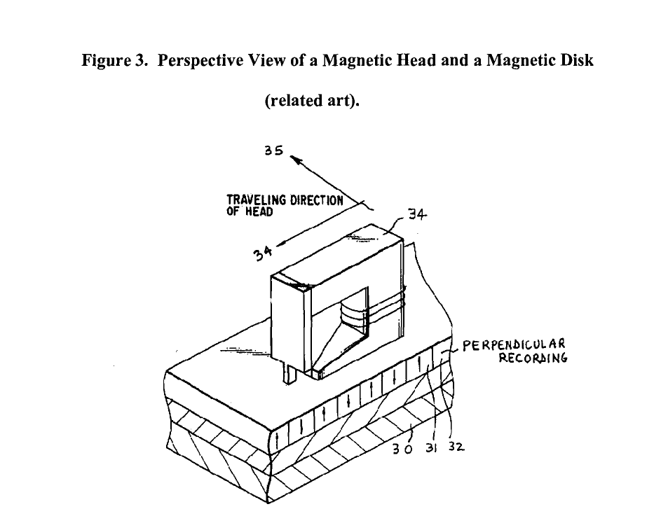

A conventional perpendicular recording disk medium, shown in FIG. 3, is similar to a longitudinal recording medium, but with the following differences. First, a conventional perpendicular recording disk medium has soft magnetic underlayer 31 of an alloy such as Permalloy instead of a Cr-containing underlayer. Second, as shown in FIG. 3, magnetic layer 32 of the perpendicular recording disk medium includes domains oriented in a direction perpendicular to the plane of the substrate 30. Also, shown in FIG. 3 are the following: (a) read-write head 33 located on the recording medium, (b) traveling direction 34 of head 33 and (c) transverse direction 35 with respect to the traveling direction 34.

The increasing demands for higher areal recording density impose increasingly greater demands on thin film magnetic recording media in terms of remanent coercivity (Hr), magnetic remanence (Mr), coercivity squareness (S*), medium noise, i.e., signal-to-medium noise ratio (SMNR), and narrow track recording performance. It is extremely difficult to produce a magnetic recording medium satisfying such demanding requirements, particularly a high-density magnetic rigid disk medium for longitudinal and perpendicular recording. The magnetic anisotropy of longitudinal and perpendicular recording media makes the easily magnetized direction of the media located in the film plane and perpendicular to the film plane, respectively. The remanent magnetic moment of the magnetic media after magnetic recording or writing of longitudinal and perpendicular media is located in the film plane and perpendicular to the film plane, respectively.

The linear recording density can be increased by increasing the Hr of the magnetic recording medium, and by decreasing the medium noise, as by maintaining very fine magnetically non-coupled grains. Medium noise in thin films is a dominant factor restricting increased recording density of high-density magnetic hard disk drives, and is attributed primarily to inhomogeneous grain size and intergranular exchange coupling. Accordingly, in order to increase linear density, medium noise must be minimized by suitable microstructure control.

In current longitudinal magnetic recording media, high areal density and low noise are achieved by statistical averaging over several hundred weakly coupled ferromagnetic grains per bit cell. Continued scaling to smaller bit and grain sizes, however, may prompt spontaneous magnetization reversal processes when the stored energy per particle starts competing with thermal energy, thereby limiting the achievable areal density. Coercivity (Hc) is a measure of the magnetic field that is needed to reverse the direction of magnetization in a thin-film layer. A material's coercivity corresponds to its magnetic strength. The unit of measure for coercivity is an Oersted (Oe).

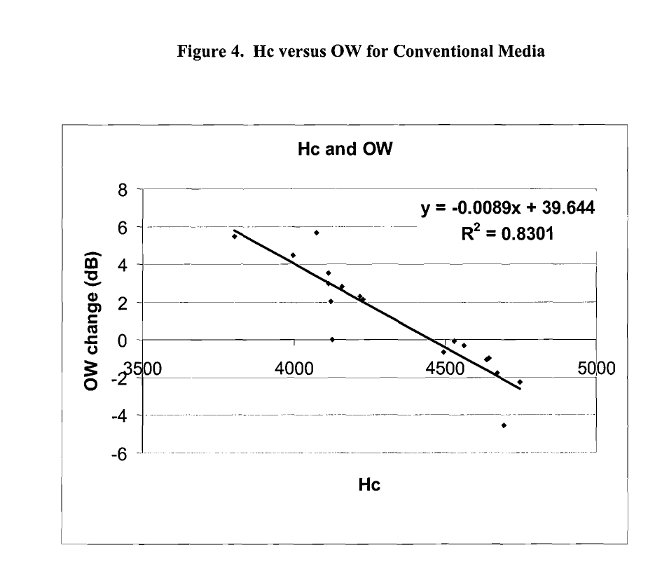

Conventional practice to achieve better thermal decay in storage media for hard disk drive applications has been to use high magnetic anisotropy energy density (Ku) materials, resulting in higher coercive force. A disadvantage of the conventional practice is the degradation of media writability, leading to poor bit-error-rate (BER) performance. FIG. 4 shows an example of the relationship between Hc and OW for conventional media—as coercivity increases, overwrite (OW) decreases. This problem is even more pronounced for media where mechanical texture is utilized to achieve the high orientation.

The present invention demonstrates a unique approach, by fabricating AFC longitudinal media with a static coercivity above 5000 Oe and a 2 dB improvement of OW over conventional media design. This invention provides magnetic recording media having different coercivity properties when writing information to the media, compared to the coercivity properties when the media is in storage. This magnetic media has the characteristic of being easy to write and hard to decay (“EWHD”). This media family can be characterized with a “kink” (i.e., a non-monotonicity) in the DC de-magnetized (DCD) curves.

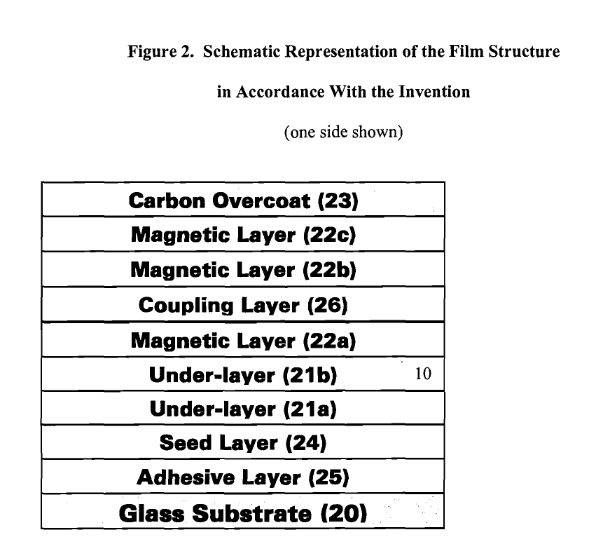

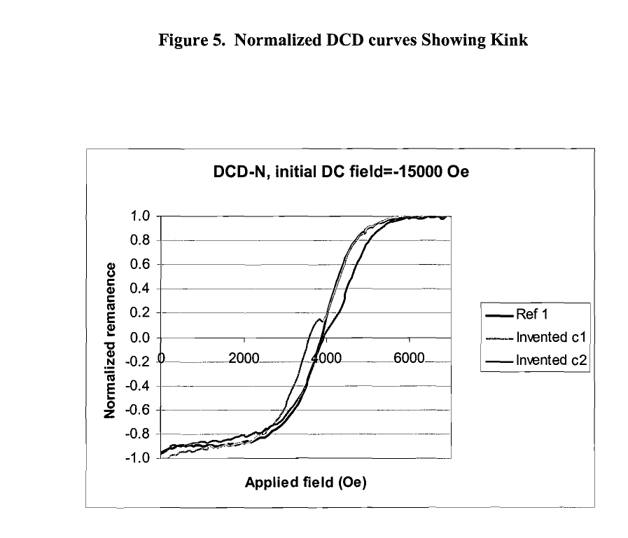

FIG. 5 shows a graph of DCD curves of the reference magnetic characteristics for a conventional magnetic recording disk known in the art, compared to two formulations of a magnetic recording disk according to the present invention. DCD curves were measured by first applying a large magnetic field of −15,000 Oe, and the media was fully magnetized in negative direction. The field was then removed and magnetic remanence was measured. The normalized remanence “−1” was then recorded in Y-axis of FIG. 5. The whole media was still maintaining magnetization in negative direction at this stage. Next, strong positive fields were applied to the media, as plotted in X-axis of FIG. 5. The field was then removed, and remanence was then measured, normalized remanence was recorded in Y-axis. The measurement ended when the field was large enough to fully revise the original magnetization and the normalized remanence became “+1”. Remanent coercivity (Hr) can be determined by the field value when the CDC curve crosses the X-axis where the normalized remanence is “0”. It is clear in FIG. 5 that a conventional disk is represented by the reference curve in the center, and the DCD is seen to be increasing generally smoothly from low to high field. The Hr of the reference curve is about 3800 Oe. There is no shift in Hr for reference curve, whereas for invented C1 and C2 curves, there are drops of about 300-500 Oe in Hr moving from 0.2 normalized remanence down to 0 due to formation of kinks at about 0.19 normalized remanence. The kink formation is due to the enhanced AFC coupling resulted from special anti-ferromagnetic spacing layer (26 in FIG. 2) described in the following sections.

FIG. 2 shows a cross sectional view of one side of a longitudinal recording disk medium having an EWHD film structure in accordance with the present invention. The invention includes a non-magnetic substrate 20, for instance glass, glass ceramics, Al/NiP, or Al—Mg alloy, which then may be electrolessly plated with a layer of NiP at a thickness of about 15 microns to increase the hardness of the substrates, thereby providing a suitable surface for polishing to provide the requisite surface roughness or texture. The substrate then has sequentially deposited on each side thereof several layers providing the desired magnetic properties.

The first layer overlying the substrate is an adhesion layer (25) of, e.g., amorphous Cr based alloy, for instance, CrTi, from 100 Å to 200 Å thick, capable of improving adhesion of seed layer (24).

Overlying the adhesion layer (25) is deposited the seed layer (24), which is typically a thin film made of structure materials having BCC or B2 crystal phases, that forms the foundation for structures that are deposited above it. Seed layer (24) also may be composed of amorphous or fine grain material. Typical composition for the seed layer (24) is B2 structure alloy NiAl or amorphous alloy CrWₓ (x≦90). Seed layer (24) is deposited using conventional thin film deposition techniques.

Overlying the seed layer (24) is deposited the first under-layer (21a) (“UL1”), which is chromium or a chromium-based alloy, such as Cr or CrMoₓTa_{y}Mn_{z} (x≦30, y≦10, z≦10). The under-layer (21a) is typically deposited by a sputtering technique. Overlying the first under-layer (21a) is an optional second under-layer (21b) (“UL2”), also made of chromium or a chromium-based alloy, such as Cr or CrMoₓTa_{y}Mn_{z} (x≦30, y≦10, z≦10). The chromium-based under-layer provides a magnetic recording media having superior magnetic property and microstructure, makes a good texture structure with Co-based magnetic layer deposited thereon and shows fine grain size distribution, high coercivity and high coercivity squaredness.

Overlying the second under-layer (21b) are the anti-ferromagnetically coupled (AFC) media layers with intermediate coupling strength, which produce a kink in the DCD curve. AFC media uses a thin layer of a material, typically ruthenium, to separate two magnetic layers on the surface of a magnetic recording disk. The AFC structure includes layers 22a, 26, 22b and 22c, which are described below in greater detail.

The first layer of the AFC structure is the stabilization layer (22a) (“ML1”), which is typically a compound of cobalt, such as CoCrₓPt_{y}B_{z}X_{α} (10≦x≦30, 5≦y≦20, 4≦z≦18, 0≦α≦5), in which “X” is an optional fifth element, for instance, Cu, Au, Ta, or V. The Co-based alloy magnetic layer is deposited by conventional techniques, and normally includes polycrystallites epitaxially grown on the under-layer (21b).

Overlying the stabilization layer (22a) is the anti-ferromagnetic coupling spacing layer (26) (“AFCL”), which is typically a compound including RuX_{y}, in which “X” is optional; if “X” is present, it may be for instance, Cr, Mo, Ti, etc., and with 0≦y≦40. The AFCL is designed to be strong enough to ensure that the magnetization of layers 22a, 22b are antiparallel in the remanent state. The AFCL maintains stability of the media with reductions in the magnetic remanence times film thickness (Mrt) ratios in between the magnetic layers. In general, the exchange coupling oscillates from ferromagnetic to anti-ferromagnetic with certain coupling/spacer film thickness, the preferred thickness being about 6˜8 Å. Preferably, the thickness of the ruthenium coupling/spacer layer 26 is selected to correspond with the first antiferromagnetic peak in the oscillation for the particular thin film structure shown in FIG. 2.

Overlying the AFC spacing layer (26) is the middle magnetic layer (22b) (“ML2”), which is typically a compound of cobalt, such as CoCrₓPt_{y}B_{z}X_{α} (8≦x≦28, 5≦y≦20, 4≦z≦18, 0≦α≦5), in which “X” is an optional fifth element, for instance, Cu, Au, Ta, V, etc.). Overlying ML2 (22b) is the top magnetic layer (22c) (“ML3”), which is typically a compound of cobalt, such as CoCrₓPt_{y}B_{z}X_{α} (4≦x≦20, 5≦y≦20, 4≦z≦18, 0≦α≦8), in which “X” is an optional fifth element, for instance, Cu, Au, Ta, V, etc. ML3 acts as a protective overcoat. ML2 or ML3 may be optional, but media performance will decrease without ML2 or ML3. ML1, ML2, and/or ML3 may be identical among themselves, but such composition of ML1-ML3 would not produce the preferred media performance. The ML1 ratio, defined as Mrt1/(Mrt1+Mrt2)*100%, may vary between >0% and 100%. The magnetic layers are typically deposited by sputtering techniques.

Optionally, an inner enhanced layer may be provided between the AFC spacing layer 26 and layer 22b.

Conventional practices also include bonding a lubricant topcoat (not shown) to ML3 (22c), e.g., a perfluoropolyether material, typically deposited by dipping or spraying.

The antiferromagnetic coupling strength can be adjusted during the sputtering process by spacer thickness and sputtering process.

The antiferromagnetic spacing layer is sputtered under conditions, which are quite different from the traditional process setting for sputtered magnetic media in at least three ways. First, conventional sputtering uses a sputtering power density of 0.10 kW, but the present invention uses a sputtering power density in a range of approximately 0.40 kW to 1.00 kW, thereby increasing the Ru sputtering power density by a factor of from 4 to 10. The resulting Ru film will be denser and the layer surface will be smoother, compared to an Ru film made with a sputtering power density outside these limits. Second, conventional sputtering uses a process delay time of 0.5 seconds, but the present invention uses a process delay time of approximately 3.6 seconds or more, thereby increasing the process delay time by a factor of ≧7. The process delay time includes sputter process cycle time, disk station to station transfer time, and Ru sputter duration time. Third, the process gas flow rate for the conventional process is 15 standard cubic centimeters per minute (sccm), but the present invention uses a process gas flow rate of approximately 36 sccm or more, thereby increasing the sputtering process Ar gas flow rate and the resulting sputtering pressure by a factor of ≧2. The Ar gas flow rate may be 40 sccm or more.

In the lab test results described below, the following acronyms may be used:

| Acronym | definition |
|---|---|
| MF TAA | Medium Frequency Track Average Amplitude |
| LF TAA | High Frequency Track Average Amplitude |
| PW50 | Pulse Width at 50% height |
| OW | Overwrite |
| NLTS | Non-Linear Transition Shift |
| PE_EFL | Position Error_Error Floor |
| OTC_EFL | On Track Capability_Error Floor |
| Esnr | Equalized Signal to Noise Ratio |
| WPE | Write Plus Erase |
| MWW | Magnetic Write Width |

Applicants have produced disks having compositions falling within the ranges identified above, and have studied the magnetic writing and decay properties of the magnetic recording materials so produced. The materials and their properties are given below in Table 1. In the discussion that follows, “KᵤV/k_{b}T” is a thermal stability factor; “Kᵤ” is the magnetic anisotropy energy density; “k_{b}” is Boltzmann's constant; T is a temperature measured in absolute degrees Kelvin; and “V” is a volume of the magnetic particle. The lab tests are summarized in Table 1:

TABLE 1

| | | | | MF | LF | | | | | OTC_EFL | | | |
|---|---|---|---|---|---|---|---|---|---|---|---|---|---|
| | | | | TAA | TAA | PW50 | OW | NLTS | | @ 5% | Esnr | WPE | MWW |
| Disc_Num | Hc | MrT | S* | (mV) | (mV) | (u″) | (dB) | (dB) | PE_EFL | SQZ | =(dB) | (u″) | (u″) |
| Ref 1 | 4821 | 0.365 | 0.819 | 0.626 | 0.765 | 3.18 | 26.80 | 18.75 | 3.74 | 3.59 | 13.09 | 7.17 | 6.21 |
| Ref 2 | 4819 | 0.349 | 0.809 | 0.583 | 0.707 | 3.16 | 27.55 | 22.99 | 3.78 | 3.37 | 13.03 | 6.99 | 6.07 |
| Ref 3 | 4391 | 0.296 | 0.822 | 0.567 | 0.671 | 3.05 | 31.27 | 17.50 | 3.86 | 3.43 | 13.15 | 7.62 | 6.66 |
| Invented | 4914 | 0.277 | 0.883 | 0.561 | 0.641 | 2.97 | 31.49 | 23.53 | 4.04 | 3.61 | 13.40 | 7.20 | 6.37 |
| C1 | | | | | | | | | | | | | |
| Invented | 5047 | 0.297 | 0.875 | 0.592 | 0.679 | 3.01 | 29.61 | 22.54 | 3.92 | 3.65 | 13.30 | 7.05 | 6.27 |
| C2 | | | | | | | | | | | | | |

Table 1 shows the parametric testing result of three separate compositions of the invented media, labeled “Invented C1,” “Invented C2” and “Invented C3.” Comparison is shown to three reference compositions of conventional media, labeled “Ref1,” “Ref2” and “Ref3.” All media including the three reference disks have the alloy compositions given in Table 2.

TABLE 2

| layer | composition | thickness (Å) |
|---|---|---|
| 23 | Carbon Overcoat | 30 |
| 22c | CoCr15Pt12B12 | 96~105 |
| 22b | CoCr23Pt12B8Cu2 | 73~85 |
| 26 | Ru | 6~8 |
| 22a | CoCr12Pt6B8 | 24~28 |
| 21b | CrMo10Ta3 | 20 |
| 21a | Cr | 34 |
| 24 | CoW40 | 34 |
| 25 | CrTi50 | 100~300 |
| 20 | Glass Substrate | |

It can be seen that the invented media has very high Hc (around 5000 Oe), but the OW is comparable to that of the conventional media with much lower Hc (Ref3), and much better than those with high Hc (Ref1 and Ref2). The BER performance of the invented media is comparable or better to that of conventional media.

In addition, the thermal amplitude decay of the invented media was improved by 0.5% per decade (Table 3). Table 3 also shows that the invented media has lower dynamic coercivity and larger KuV/kbT, resulted from Sharrock fits. VSM measurement in FIG. 5 revealed that all of the invented media had a kink in their DCD curves. These kinks are the main source for low dynamic coercivity at writing mode (easy to write), and high static coercivity so as to higher thermal stability during storage (hard to decay).

TABLE 3

| Items | unit | Ref 1 | Invented C1 | Invented C2 |
|---|---|---|---|---|
| Ho dynamic | Oe | 7451 ± 60 | 6605 ± 133 | 7146 ± 118 |
| coercivity | | | | |
| KuV/kbT | | 73 ± 1 | 95 ± 5 | 96 ± 4 |
| Thermal decay | (% decade) | 1.8 | 1.47 | 1.31 |
| Jex | erg/cm² | 0 | 0.042 | 0.043 |

Jex is the interlayer exchange coupling energy.

The above description is presented to enable a person skilled in the art to make and use the invention, and is provided in the context of a particular application and its requirements. Various modifications to the preferred embodiments will be readily apparent to those skilled in the art, and the generic principles defined herein may be applied to other embodiments and applications without departing from the spirit and scope of the invention. Thus, this invention is not intended to be limited to the embodiments shown, but is to be accorded the widest scope consistent with the principles and features disclosed herein.

This application discloses several numerical range limitations. Persons skilled in the art would recognize that the numerical ranges disclosed inherently support any range within the disclosed numerical ranges even though a precise range limitation is not stated verbatim in the specification because this invention can be practiced throughout the disclosed numerical ranges. A holding to the contrary would “let form triumph over substance” and allow the written description requirement to eviscerate claims that might be narrowed during prosecution simply because the applicants broadly disclose in this application but then might narrow their claims during prosecution. Where the term “plurality” is used, that term shall be construed to include the quantity of one, unless otherwise stated. The entire disclosure of the patents and publications referred in this application are hereby incorporated herein by reference. Finally, the implementations described above and other implementations are within the scope of the following claims.

1. A magnetic recording media disk having an enhanced change in magnetic coercivity from a writing state of the disk to a non-writing state of the disk, prepared by a process comprising the steps of:
providing a platter having an outer layer comprising a first layer of magnetic material;
securing the platter in a vacuum within a sputtering chamber having at least one sputtering cathode;
introducing argon gas into the sputtering chamber at a pressure of at least 4 mtorr, the argon gas having a flow rate of at least 36 sccm;
pausing at least 3.6 seconds;
sputtering an anti-ferromagnetic coupling spacing layer onto the platter, the sputtering cathode having a power density of at least 0.4 kW to 1.0 kW;
sputtering a second layer of magnetic material onto the anti-ferromagnetic coupling spacing layer;
applying a carbon overcoat to the sputtered platter.

2. The magnetic recording media disk according to claim 1, wherein the anti-ferromagnetic coupling spacing layer comprises RuX_{y}, wherein 0≦y≦40, and X is selected from the group consisting of Cr, Mo, and Ti.

3. The magnetic recording media disk according to claim 1, wherein the first layer of magnetic material comprises CoCrₓPt_{y}B_{z}, wherein 10≦x≦30, 5≦y≦20, and 4≦z≦18.

4. The magnetic recording media disk according to claim 1, wherein the first layer of magnetic material comprises CoCrₓPt_{y}B_{z}X_{α}, wherein 10≦x≦30, 5≦y≦20, 4≦z≦18, 0≦α≦5, and X is selected from the group consisting of Cu, Au, Ta, and V.

5. The magnetic recording media disk according to claim 1, wherein the second layer of magnetic material comprises CoCrₓPt_{y}B_{z}, wherein 8≦x≦28, 5≦y≦20, and 4≦z≦18.

6. The magnetic recording media disk according to claim 1, wherein the second layer of magnetic material comprises CoCrₓPt_{y}B_{z}X_{α}, wherein 8≦x≦28, 5≦y≦20, 4≦z≦18, 0≦α≦5, and X is selected from the group consisting of Cu, Au, Ta, and V.

7. The magnetic recording media disk according to claim 1, comprising the further step of sputtering a third layer of magnetic material onto second layer of magnetic material before applying the carbon overcoat.

8. The magnetic recording media disk according to claim 7, wherein the third layer of magnetic material comprises CoCrₓPt_{y}B_{z}, wherein 4≦x≦20, 5≦y≦20, and 4≦z≦18.

9. The magnetic recording media disk according to claim 7, wherein the third layer of magnetic material comprises CoCrₓPt_{y}B_{z}X_{α}, wherein 4≦x≦20, 5≦y≦20, 4≦z≦18, 0≦α≦8, and X is selected from the group consisting of Cu, Au, Ta, and V.

10. A process for producing a magnetic recording media disk having an enhanced change in magnetic coercivity from a writing state of the disk to a non-writing state of the disk, comprising the steps of:
providing a platter having an outer layer comprising a first layer of magnetic material;
securing the platter in a vacuum within a sputtering chamber having at least one sputtering cathode;
introducing argon gas into the sputtering chamber at a pressure of at least 4 mtorr, the argon gas having a flow rate of at least 36 sccm;
pausing at least 3.6 seconds;
sputtering an anti-ferromagnetic coupling spacing layer onto the platter, the sputtering cathode having a power density of at least 0.4 kW to 1.0 kW;
sputtering a second layer of magnetic material onto the anti-ferromagnetic coupling spacing layer;
applying a carbon overcoat to the sputtered platter.

11. The process of claim 10, comprising the further step of sputtering a third layer of magnetic material onto second layer of magnetic material before applying the carbon overcoat.

12. A magnetic recording media disk having an enhanced change in magnetic coercivity from a writing state of the disk to a non-writing state of the disk, comprising:
a substrate comprising a non-magnetic material, the substrate electrolessly plated on at least one side with a layer of NiP at a thickness of about 15 microns;
an adhesive layer of from 25 Å to 50 Å thick overlying the layer of NiP, comprising a material selected from the group consisting of Cr, Cr-alloy, and Ti, wherein the adhesive layer is capable of controlling the crystallographic texture of Co-based alloys;
a seed layer overlying the adhesive layer, the seed layer comprising a material selected from the group consisting of a material having BCC crystal phase, a material having B2 crystal phase, an amorphous material, a fine grain material, NiAl, and CrWₓ, wherein x≦90;
a first under-layer overlying the seed layer, the first under-layer comprising a material selected from the group consisting of Cr and CrMoₓTa_{y}Mn_{z}, wherein x≦30, y≦10, and z≦10;
a second under-layer, overlying the first under-layer, the second under-layer comprising a material selected from the group consisting of Cr and CrMoₓTa_{y}Mn_{z}, wherein x≦30, y≦10, and z≦10;
a first magnetic layer, overlying the second under-layer, comprising a compound of cobalt;
an anti-ferromagnetic coupling spacing layer, overlying the first magnetic layer, comprising RuX_{y}, wherein 0≦y≦40, and X is selected from the group consisting of Cr, Mo, and Ti;
a second magnetic layer, overlying the anti-ferromagnetic coupling spacing layer, wherein the second magnetic layer comprises a compound of cobalt;
a third magnetic layer, overlying the second magnetic layer, wherein the third magnetic layer comprises a compound of cobalt;
a carbon overcoat overlying the third magnetic layer.

13. The magnetic recording media disk of claim 12, wherein the first magnetic layer comprises CoCrₓPt_{y}B_{z}, wherein 10≦x≦30, 5≦y≦20, and 4≦z≦18.

14. The magnetic recording media disk of claim 12, wherein the first magnetic layer comprises CoCrₓPt_{y}B_{z}X_{α}, wherein 10≦x≦30, 5≦y≦20, 4≦z≦18, and 0≦α≦5, and X is selected from the group consisting of Cu, Au, Ta, and V.

15. The magnetic recording media disk of claim 12, wherein the second magnetic layer comprises CoCrₓPt_{y}B_{z}, wherein 8≦x≦28, 5≦y≦20, and 4≦z≦18.

16. The magnetic recording media disk of claim 12, wherein the second magnetic layer comprises CoCrₓPt_{y}B_{z}X_{α}, wherein 8≦x≦28, 5≦y≦20, 4≦z≦18, and 0≦α≦5, and X is selected from the group consisting of Cu, Au, Ta, and V.

17. The magnetic recording media disk of claim 12, wherein the third magnetic layer comprises CoCrₓPt_{y}B_{z}, wherein 4≦x≦20, 5≦y≦20, 4≦z≦18.

18. The magnetic recording media disk of claim 12, wherein the third magnetic layer comprises CoCrₓPt_{y}B_{z}X_{α}, wherein 4≦x≦20, 5≦y≦20, 4≦z≦18, and 0≦α≦8, and X is selected from the group consisting of Cu, Au, Ta, and V.
